(19) United States
(12) Patent Application Publication
(10) Pub. No.: US 2007/0032073 A1
(43) Pub. Date: Feb. 8, 2007

(54) Method of substrate processing and apparatus for substrate processing

(76) Inventor: Yasuo Kobayashi, Nirasaki-Shi (JP)

Correspondence Address: SMITH, GAMBRELL & RUSSELL, 1850 M STREET, N.W., SUITE 800, WASHINGTON, DC, 20036, US

(21) Appl. No.: 10/571,256

(22) PCT Filed: Sep. 1, 2004
(86) PCT No.: PCT/JP04/12647

§ 371 Date: Mar. 9, 2006

(30) Foreign Application Priority Data
Sep. 19, 2003 (JP) 2003-328226

(51) Int. Cl. H01L 21/44

(52) U.S. Cl. 438/655; 438/682; 438/683; 438/706; 438/660

(57) ABSTRACT

In a substrate-processing method and a substrate-processing apparatus according to the invention, a natural oxide film that has been formed on each surface layer of a gate 21, a source 15 and a drain 17 of a MOSFET 11 is removed by an NF₃ gas that has been activated. Then, a Co film 91 is formed on each surface of the gate 21, the source 15 and the drain 17 from which the natural oxide film has been removed. Then, a low-temperature annealing process is conduced to the MOSFET, so that the Co film 91 and each silicon compound of the gate 21, the source 15 and the drain 17 react with each other. Thus, a metal silicide layer is formed on a surface layer of each silicon compound. Therefore, a processing method without a high-temperature annealing process, whose thermal history may have an adverse effect on distribution of impurities in the substrate, can be provided.

### FIELD OF THE INVENTION

This invention relates to a substrate processing method and a substrate processing apparatus for forming a metal silicide layer on a surface layer of a silicon material layer.

### BACKGROUND ART

As a level of an integration of a semiconductor device is enhanced, for example in a MOSFET, reduction of resistance of a source and a drain, which are impurity diffusion layers, has become more important.

As a method for the reduction of resistance of the impurity diffusion layers, a silicidation method has been developed, wherein a metal silicide layer whose electric resistance is low is formed on surfaces of the impurity diffusion layers. In detail, according to a silicidation method, a thin metal film that can be silicided is deposited on the whole surface of a silicon material layer, and a thermal process (an annealing process for silicidation) is conducted so that a silicidation reaction is caused at a contact portion of the thin metal film and the silicon material layer in order to form a metal silicide.

In order to conduct the silicidation process, a natural oxide film that has been formed on the surface of the silicon material layer has to be removed before the silicidation process. Conventionally, as a method of removing the natural oxide film, a wet cleaning process using DHF(HF/H₂O) or the like is adopted.

In addition, as conventional arts, there are known JP Laid-Open Publication No. 2000-315662 and JP Laid-Open Publication No. Hei 10-335316.

Herein, in a method adopting a DHF cleaning process, in order to sufficiently reduce the resistance of the metal silicide layer, the annealing process has to be conducted at 550° C. or higher. A graph of FIG. 6 reveals the fact. From the graph, when a DHF cleaning process is adopted, it is found that the temperature has to be at 550° C. or higher in order to control the resistance of a cobalt silicide to about 60 ohm/sq. The reason is that a small amount of oxide film remains on the silicon material layer even after the DHF cleaning process and hence the silicidization needs more energy.

However, when the temperature for the annealing process is high, such thermal history may have an adverse effect on distribution of impurities in the substrate.

### SUMMARY OF THE INVENTION

This invention is intended to solve the above problems. The object of this invention is to provide a substrate processing method and a substrate processing apparatus that need no high-temperature process for forming a metal silicide.

In order to achieve the above object, an invention according to claim 1 is a substrate processing method comprising the steps of: removing an oxide film, which has been formed on a surface layer of a silicon compound, by means of a reaction gas that has been activated; forming a metal film on the surface layer of the silicon compound after the oxide film has been removed; and forming a metal silicide on the surface layer of the silicon compound by means of a reaction of the metal film that has been formed thereon and the silicon compound. Thus, the invention can provide a processing method without a high-temperature annealing process whose thermal history may have an adverse effect on distribution of impurities in the substrate.

An invention according to claim 2 has a feature that the step of forming a metal film on the surface layer of the silicon compound and the step of forming a metal silicide are conducted at the same time.

An invention according to claim 3 has a feature that the reaction of the metal film that has been formed and the silicon compound is conducted by an annealing process, and a feature that the reaction of the metal film that has been formed and the silicon compound is conducted after the step of forming a metal film on the surface layer of the silicon compound.

An invention according to claim 4 has a feature that the reaction gas is NF₃.

An invention according to claim 5 has a feature that the step of activating the reaction gas is conducted by adding the reaction gas to an activating gas that has been activated by plasma.

An invention according to claim 6 has a feature that the activating gas is a mixed gas of N₂ and H₂

An invention according to claim 7 has a feature that the metal film is a Co film.

An invention according to claim 8 has a feature that the metal film is a Ni film.

An invention according to claim 9 has a feature that a step of forming an antioxidant film on the metal film that has been formed is further provided between the step of forming a metal film on the surface layer of the silicon compound and the step of forming a metal silicide.

An invention according to claim 10 has a feature that the antioxidant film is a TiN film.

An invention according to claim 11 is a substrate processing method for a MOS transistor having side walls between a gate region and a source region or a drain region, the method comprising the steps of: removing an oxide film, which has been formed on a surface layer of the gate region, the source region and the drain region, by means of a reaction gas that has been activated; forming a metal film on the surface layer of the gate region, the source region and the drain region after the oxide film has been removed; and forming a metal silidde on the surface layer of the gate region, the source region and the drain region, by annealing the gate region, the source region and the drain region on which the metal film has been formed.

An invention according to claim 12 is a substrate processing apparatus comprising: an oxide-film removing chamber for removing an oxide film, which has been formed on a surface layer of a silicon compound, by means of a reaction gas that has been activated; a metal-film forming chamber for forming a metal film on the surface layer of the silicon compound after the oxide film has been removed; and a conveyance chamber connected to the oxide-film removing chamber and the metal-film forming chamber, having a conveying apparatus that conveys an object to be processed between the oxide-film removing chamber and the metal-film forming chamber.

An invention according to claim 13 is a substrate processing apparatus comprising: a modified film forming chamber for forming a modified film by causing an oxide film, which has been formed on a surface layer of a silicon compound, to react with a reaction gas that has been activated; a modified film removing chamber for heating the silicon compound, on which the modified film has been formed, in order to evaporate the modified film and remove the same; a metal-film forming chamber for forming a metal film on the surface layer of the silicon compound after the modified film has been removed; and a conveyance chamber connected to the modified film forming chamber and the modified film removing chamber and the metal-film forming chamber, filled with a unreactive gas, having a conveying apparatus that conveys an object to be processed between the modified film forming chamber and the modified film removing chamber and the metal-film forming chamber.

### BRIEF DESCRIPTION OF THE DRAWINGS

FIG. 1 is a schematic sectional view showing a first step for conducting a process to a MOSFER by a substrate processing method according to an embodiment of the present invention;

FIG. 2 is a schematic sectional view showing a second step for conducting the process to the MOSFET by the substrate processing method according to the embodiment of the present invention;

FIG. 3 is a schematic sectional view showing a third step for conducting the process to the MOSFET by the substrate processing method according to the embodiment of the present invention;

FIG. 4 is a schematic plan view showing a substrate processing apparatus according to an embodiment of the present invention;

FIG. 5 is a schematic sectional view showing a low-temperature processing chamber that conducts a low-temperature process in the embodiment of the present invention; and

FIG. 6 is a graph showing a relationship between annealing temperature and resistance of cobalt silicide, in a case wherein a DHF cleaning process has been conducted and in a case wherein an NOR cleaning process has been conducted.

### DESCRIPTION OF THE PREFERRED EMBODIMENT

Hereinafter, embodiments of the present invention are explained in detail with reference to FIGS. 1 to 6.

FIG. 1 is a schematic sectional view showing a MOSFET 11 to which a processing method of the present invention is applied. In FIG. 1, the numeral sign 13 shows a silicon substrate. A source 15 and a drain 17, which are impurities diffusion layers, are respectively provided on both lateral sides of the silicon substrate 13. A gate 21 consisting of a polycrystalline silicon is provided at an exposed portion of the silicon substrate between the source 15 and the drain 17, via a gate oxide film 19. Then, side walls 23 are provided at both lateral sides of the gate 21.

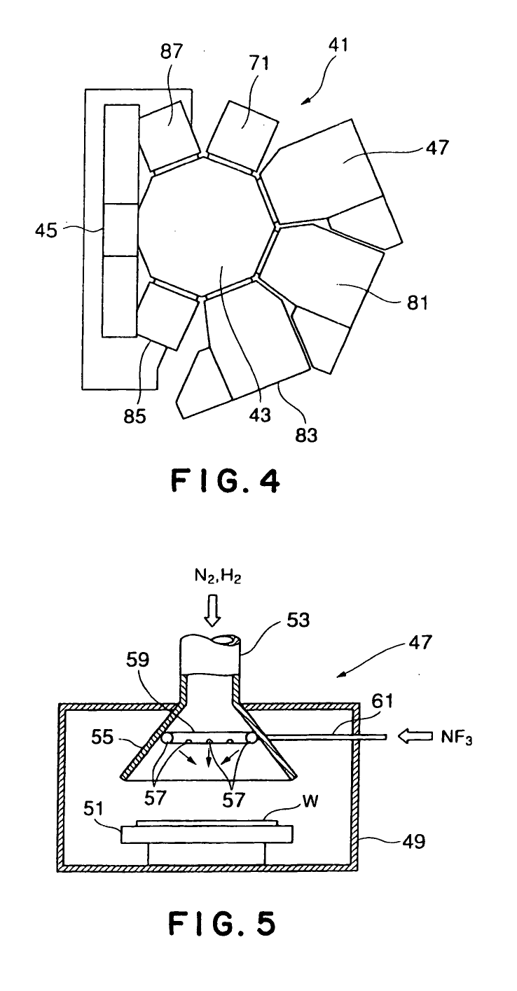

The MOSFET 11 is processed by a substrate processing apparatus 41 as shown in FIG. 4. The substrate processing apparatus 41 has a conveyance chamber 43 at a central portion thereof. A conveying apparatus for conveying a wafer is provided in the conveyance chamber 43. The inside of the conveying chamber 43 is filled with a unreactive atmosphere, for example a vacuum. Thus, it can be prevented that a natural oxide film is generated on a wafer W while the wafer W is conveyed. The conveying chamber 43 is connected to a load-lock chamber 45 that is installed to load a unprocessed wafer W into the conveying chamber 43.

A low-temperature processing chamber 47 is connected to the conveying chamber 43, on the opposite side of the load-lock chamber 45.

As shown in FIG. 5, the low-temperature processing chamber 47 has a processing container 49 in which a vacuum can be created. A stage 51 for placing the wafer W to be processed thereon is provided in the processing container 49. On the other hand, a plasma forming pipe 53 is provided at a ceiling wall of the processing container 49. Through the plasma forming pipe 53, an N₂ gas and an H₂ gas that have been activated by plasma are supplied into the processing container 49. A cover member 55 having a shape of an umbrella expanding downwardly is connected to a lower end of the plasma forming pipe 53, so that the gases can flow efficiently toward the wafer W on the stage 51.

On the inner side of the cover member 55, a circular showerhead 59 having a large number of gas holes 57 is arranged. A communication pipe 61 is connected to the showerhead 59. An NF₃ gas is supplied to the showerhead 59 via the communication pipe 61, and supplied into the cover member 55 through the large number of gas holes 57. Thus, the NF₃ gas collides with the active species of the N₂ gas and the H₂ gas in the cover member 55, so that the NF₃ gas is also activated. Then, the activated NF₃ gas reacts with a natural oxide film that has been formed on the surface of the MOSFET on the wafer W, in order to form a modified film.

A heating chamber 71 is connected to the conveyance chamber 43, adjacent to the low-temperature processing chamber 47. The wafer W is conveyed into the heating chamber 71 from the low-temperature processing chamber 47 via the conveyance chamber 43. In the heating chamber 71, the modified film, which has been formed on the surface of the MOSFET on the wafer W in the low-temperature processing chamber 47, is heated and evaporated, so that the wafer surface is cleaned.

A Co-sputtering chamber 81 is connected to the conveyance chamber 43, on the opposite side of the heating chamber 71 with respect to the low-temperature processing chamber 47. A TiN-sputtering chamber 83 is also connected to the conveyance chamber 43, adjacent to the Co-sputtering chamber 81. In the Co-sputtering chamber 81, a Co film is formed on the cleaned surface of the MOSFET by means of sputtering. Then, in the subsequent TiN-sputtering chamber 83, a TiN film is formed on the Co film by means of sputtering.

An annealing chamber 85 is connected to the conveyance chamber 43, adjacent to the TiN-sputtering chamber 83. In the annealing chamber 85, an annealing process is conducted to the wafer W on which the Co film has been formed.

In addition, a cooling chamber 87 is connected to the conveyance chamber 43, adjacent to the heating chamber 71. In the cooling chamber 87, the processed and heated wafer W is cooled. Thus, thereafter, the wafer doesn't react with a reactive atmosphere even when the wafer is conveyed into the reactive atmosphere.

Next, a method of silicidation a MOSFET by means of the above substrate processing apparatus 41 is explained with reference to FIGS. 1 to 3.

At first, a MOSFET as shown in FIG. 1 is conveyed into the low-temperature processing chamber 47 as shown in FIG. 4. Then, in the low-temperature processing chamber 47, the activated NF₃ gas and the natural oxide film are caused to react with each other, in order to form a modified film.

Then, the MOSFET is conveyed into the heating chamber 71, and heated therein. Thus, the modified film is evaporated, and hence the surface of the MOSFET is cleaned (hereinafter, the cleaning method is referred to as NOR cleaning.)

Then, the MOSFET whose surface has been cleaned as described above is conveyed into the Co-sputtering chamber 81.

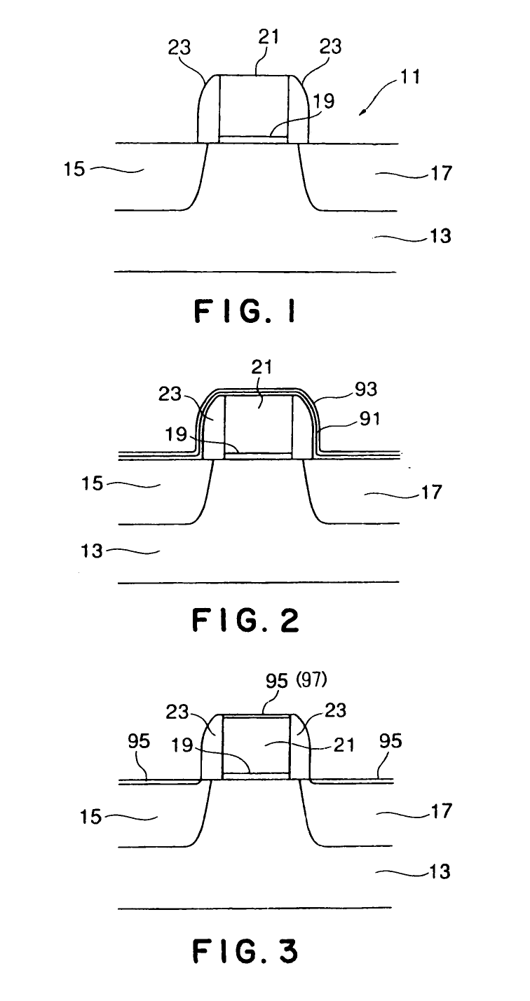

As described above, the MOSFET whose surface has been cleaned is conveyed into the Co-sputtering chamber 81. Then, as shown in FIG. 2, a Co film 91 is formed on the surface. After that, the MOSFET is conveyed into the TiN-sputtering chamber 83. Then, a TiN film 93 is formed on the surface. The TiN film 93 functions to prevent the Co film 91 from being oxidized.

Next, the MOSFET is conveyed into the annealing chamber 85. In the annealing chamber 85, the MOSFET is subjected to an annealing process at a low temperature (450 to 550° C.), so that a CoSi layer 95 is formed on each surface of the source 15, the drain 17 and the gate 21. The Co—Si layer 95 functions as a mask at a cleaning process that is conducted thereafter, differently from a CoSi₂ layer described below.

The reason why the annealing process can be conducted at a low-temperature (450 to 550° C.) is as follows.

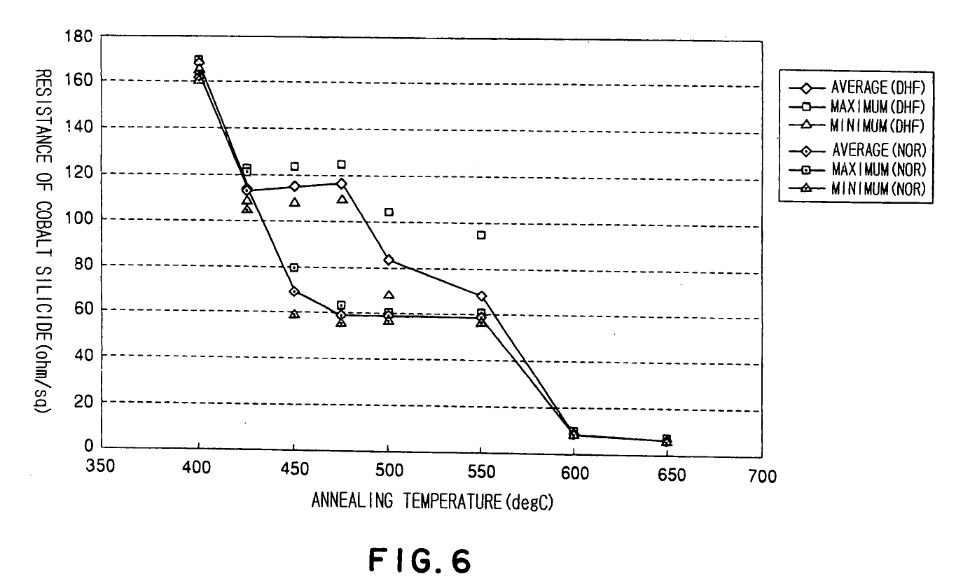

That is, as shown in FIG. 6, when the NOR cleaning is adopted, the resistance of the Cobalt silicide (Co—Si) can be reduced to 60 ohm/sq at an annealing temperature of 450 to 550° C. Thus, according to the present substrate processing method, an annealing process can be conducted at a much lower temperature than when a DHF cleaning is adopted. Thus, it can be prevented that thermal history of a high-temperature annealing process may have an adverse effect on distribution of impurities in the substrate.

Next, the MOSFET is conveyed out through the conveyance chamber 43 and the load-lock chamber 45, and conveyed into a metal cleaning chamber (not shown). Then, in the metal cleaning chamber, an SPM cleaning process is conducted, so that the remaining Co film and the remaining TiN film are removed. Herein, the CoSi layer 95 that has been formed before cannot be dissolved by the SPM cleaning process. Thus, as shown in FIG. 3, the CoSi layer 95 is exposed on each surface of the gate 21, the source 15 and the drain 17.

Then, the MOSFET is conveyed from the metal cleaning chamber into the second annealing chamber (not shown), and subjected to another annealing process at 650° C. or higher. Thus, the CoSi layer 95 that has been formed on the surfaces of the source 15, the drain 17 and the gate 21 is changed into a CoSi₂ layer 97, which is a cobalt silicide layer achieving a lower resistance.

Thus, according to the above substrate processing method, the natural oxide film formed on the surface layers of the gate 21, the source 15 and the drain 17 of the MOSFET 11 is removed by the activated NF₃ gas, the Co film 91 is formed on the surfaces of the gate 21, the source 15 and the drain 17 from which the natural oxide film has been removed, and the MOSFET is subjected to the low-temperature annealing process (450 to 550° C.), so that the Co film 91 and the silicon compound of the gate 21, the source 15 and the drain 17 are caused to react with each other in order to form the metal silicide layer on the surface layer of the silicon compound. Thus, compared with the case wherein the natural oxide film is removed by the DHF cleaning process, the annealing process can be conducted at the lower temperature, and hence it can be prevented that thermal history of a high-temperature annealing process may have an adverse effect on distribution of impurities in the substrate.

In addition, since the TiN film 93 is formed on the surface of the Co film 91, it can be prevented that the Co film is oxidized after the Co film has been formed.

In addition, the above substrate processing apparatus 41 comprises: the low-temperature processing chamber 47 for causing the activated reaction gas to react with the oxide film formed on the surface layer of the silicon compound in order to form the modified film; the heating chamber 71 for heating the silicon compound on which the modified film has been formed and hence evaporating the modified film in order to remove the same; the Co-sputtering chamber 81 for forming the metal film on the surface of the silicon compound from which the modified film has been removed; and the conveyance chamber 43 connected to the low-temperature processing chamber 47, the heating chamber 71 and the Co sputtering chamber 81, having the conveying apparatus that conveys the wafer in the unreactive atmosphere between the low-temperature processing chamber 47, the heating chamber 71 and the Co sputtering chamber 81. Thus, the removal of the oxide film, the forming of the Co film, and the forming of the Co silicide layer can be conducted efficiently. In addition, it can be prevented that undesired oxidization is caused during the above processes.

Herein, in the above embodiment, after the step of forming the Co film on the surfaces of the gate, the source and the drain, the step of forming the cobalt silicide is conducted. However, the invention is not limited thereto. For example, the step of forming the Co film on the surfaces of the gate, the source and the drain and the step of forming the cobalt silicide may be conducted at the same time. In this case, the processes (steps) can be shortened, and hence the throughput can be improved.

In addition, in the above embodiment, the Co film is formed on the surfaces of the gate, the source and the drain of the MOSFET. However, the invention is not limited thereto. For example, a Ni film may be formed thereon.

Furthermore, in the above embodiment, the Cobalt silidde is formed on the surfaces of the gate, the source and the drain of the MOSFET. However, the invention is not limited thereto. This invention can be applied to any case wherein a metal silicide is formed on a surface layer of a silicon compound from which an oxide film has been removed. For example, the invention can be applied to an elevated source and/or an elevated drain.

1. A substrate processing method comprising the steps of:
removing an oxide film, which has been formed on a surface layer of a silicon compound, by means of a reaction gas that has been activated;
forming a metal film on the surface layer of the silicon compound after the oxide film has been removed; and
forming a metal silicide on the surface layer of the silicon compound by means of a reaction of the metal film that has been formed thereon and the silicon compound.

2. A substrate processing method according to claim 1, wherein
the step of forming a metal film on the surface layer of the silicon compound and the step of forming a metal silicide are conducted at the same time.

3. A substrate processing method according to claim 1, wherein
the reaction of the metal film that has been formed and the silicon compound is conducted by an annealing process, and
the reaction of the metal film that has been formed and the silicon compound is conducted after the step of forming a metal film on the surface layer of the silicon compound.

4. A substrate processing method according to claim 1, wherein
the reaction gas is NF₃.

5. A substrate processing method according to claim 1 or 14, wherein
the step of activating the reaction gas is conducted by adding the reaction gas to an activating gas that has been activated by plasma.

6. A substrate processing method according to claim 5, wherein
the activating gas is a mixed gas of N₂ and H₂.

7. A substrate processing method according to claim 1 or 14, wherein
the metal film is a Co film.

8. A substrate processing method according to claim 1 or 14, wherein
the metal film is a Ni film.

9. A substrate processing method according to claim 1 or 14, further comprising
a step of forming an antioxidant film on the metal film that has been formed, between the step of forming a metal film on the surface layer of the silicon compound and the step of forming a metal silicide.

10. A substrate processing method according to claim 9, wherein
the antioxidant film is a TiN film.

11. (canceled)

12. (canceled)

13. (canceled)

14. A substrate processing method comprising the steps of:
forming a modified film by causing an oxide film, which has been formed on a surface layer of a silicon compound, and a NF₃ gas, which has been activated, to react with each other;
heating and evaporating the modified film in order to remove the same;
forming a metal film on the surface layer of the silicon compound after the oxide film has been removed; and
forming a metal silicide on the surface layer of the silicon compound by means of an annealing process of the metal film that has been formed thereon and the silicon compound at a temperature of 450 to 550° C.

15. A substrate processing method according to claim 14, wherein
the metal silicide that has been formed on the surface layer on the silicon compound is further annealed at a temperature of 650° C. or higher.

16. A substrate processing method according to claim 14, wherein
the activating gas is a mixed gas of N₂ and H₂.

17. A substrate processing method according to claim 14, wherein
the antioxidant film is a TiN film.
